(19) United States
(12) Patent Application Publication
(10) Pub. No.: US 2024/0024840 A1
(43) Pub. Date: Jan. 25, 2024

(54) Methods and Apparatus for Delivering Feedstocks for Plasma Treatment

(71) Applicant: Haydale Graphene Industries PLC, Carmarthenshire, South Wales (GB)

(72) Inventors: John-Mark Seymour, Carmarthenshire, South Wales (GB); Thomas Howe, Carmarthenshire, South Wales (GB); Lee Edwards, Carmarthenshire, South Wales (GB)

(21) Appl. No.: 18/027,082

(22) PCT Filed: Sep. 8, 2021
(86) PCT No.: PCT/EP2021/074727

§ 371 Date: Mar. 17, 2023

(30) Foreign Application Priority Data
Sep. 18, 2020 (GB) 2014776.5
Sep. 18, 2020 (GB) 2014779.9

(51) Int. Cl. B01J 19/08

(52) U.S. Cl. CPC B01J 19/088; B01J 2219/0898; B01J 2219/00488; B01J 2219/00355; B01J 2219/00186; B01J 2219/00162

(57) ABSTRACT

The present application relates to methods and apparatus for delivering liquid or solid feedstocks into a plasma treatment vessel. More specifically, the invention provides a method for treating a sample using glow discharge plasma in an apparatus comprising a treatment vessel, the method comprising (i) delivering a gaseous plasma forming feedstock into the treatment vessel through a gas supply line under the control of a gas flow controller, and causing formation of a glow discharge plasma in the treatment vessel from the gaseous plasma forming feedstock; and simultaneously (ii) delivering a reagent into the treatment vessel under the control of a reagent dosing controller, wherein the reagent is a liquid or a solid; and (iii) contacting the sample with the glow discharge plasma and the reagent; wherein the gas flow controller and the reagent dosing controller allow independent control of the rate of delivery of the gaseous plasma forming feedstock and the reagent.

### FIELD OF THE INVENTION

This invention relates to methods and apparatus for plasma treatment of a sample, in particular, methods and apparatus for delivering feedstocks for plasma treatment of particulate samples.

### BACKGROUND OF THE INVENTION

Glow discharge plasma treatment is a method which can be used to treat a wide range of materials. This includes the treatment of particulate materials, as disclosed in our own earlier patent applications WO 2010/142953 and WO 2012/076853.

In order to efficiently treat a material with glow discharge plasma, it is generally necessary to operate plasma treatment for sustained periods of time under closely controlled low-pressure conditions.

Materials may be chemically functionalised in a glow discharge plasma treatment reaction by components derived from the plasma-forming feedstock, forming e.g. carboxy, carbonyl, hydroxyl, amine, amide or halogen functionalities on their surfaces, as disclosed in WO 2012/076853. The process is clean and efficient, and it is possible to accurately control the level of functionalisation on the materials' surface based on the treatment times used.

However, some desirable surface chemistries are not readily accessible through plasma treatment using gaseous plasma feedstocks. This includes, for example, functionalisation with silanes, or decoration of the surface with metals.

One known method of introducing these chemistries to the surface of materials involves using wet chemistry. However, these types of chemical methods can have a range of disadvantages. For example, they are often environmentally unfriendly, can require toxic reagents (sometimes in large quantities), and often necessitate copious washing after treatment. Also, in some instances high temperatures are required in order to access specific functionalities, such as the introduction of metals. In addition, wet chemical methods often require large quantities of different reagents meaning that these methods can be costly.

Plasma-based methods for introducing such chemistries have also been described.

For example, WO 2015/145172 describes the decoration of graphene materials with silane functionality using the volatile liquid hexamethyldisiloxane. The hexamethyldisiloxane is introduced into a glow plasma reactor using a “bubbler system”. In such a system, an argon carrier gas is bubbled into a reservoir of hexamethyldisiloxane held in a closed container, and the resulting pressurised hexamethyldisloxane-containing vapour in the headspace of the container is flowed into the glow discharge plasma reactor. However, these types of bubbler system can only be used with liquids which vaporise easily, and it is difficult to control and tune the characteristics of the functionalisation.

The same document (WO 2015/145172) also describes decoration of graphene with metals during glow discharge plasma treatment. This is achieved through use of a metal electrode which deposits onto the graphene during treatment. However, this process limits the type of metals which can be deposited to those compatible with use as/on an electrode and necessarily results in electrode degradation. In addition, the characteristics (e.g. stability, level of arcing) of the plasma will unavoidably be impacted by the need to tailor the conditions to achieve decoration with metals. This results in significant limitations in terms of the type, level and cost of the metal introduction.

Consequently, there remains a need in the art to develop improved methods for extending the capabilities of plasma processing to a broader range of feedstocks.

### SUMMARY OF THE INVENTION

In view of the above problems, in a first aspect the present invention provides a method for treating a sample using glow discharge plasma in an apparatus comprising a treatment vessel, the method comprising:
delivering a gaseous plasma forming feedstock into the treatment vessel through a gas supply line under the control of a gas flow controller, and causing formation of a glow discharge plasma in the treatment vessel from the gaseous plasma forming feedstock; and simultaneously
delivering a reagent into the treatment vessel under the control of a reagent dosing controller, wherein the reagent is a liquid or a solid; and
contacting the sample with the glow discharge plasma and the reagent;
wherein the gas flow controller and the reagent dosing controller allow independent control of the rate of delivery of the gaseous plasma forming feedstock and the reagent.

The method according to the present invention has a number of advantageous features compared to the systems taught in WO 2015/145172.

Firstly, the method according to the present invention allows liquid and solid reagents to be accurately fed into the treatment vessel independently of the rate at which a carrier gas (e.g. the gaseous plasma forming feedstock) is supplied—in other words, the rate of delivery of gas to the treatment vessel can be decoupled from the rate of delivery of liquid/solid. This is in contrast to the type of bubbler system taught in WO2015/145172 where the rate of delivery of the carrier gas determines the amount of liquid carried into the treatment vessel. The present invention, therefore, allows bespoke levels of functionalisation to be achieved and large scale reactions to be performed, which opens up the possibility of tuning the level of liquid or solid reagent that can be supplied to the treatment vessel.

Secondly, the method according to the present invention can be used with non-volatile liquid and solid reagents. This opens up the method to a wide variety of metals and non-volatile chemicals, for example, silanes such as APTES. The use of these reagents is not compatible with bubbler systems, due to their lack of volatility. These liquid and solid reagents can be used to produce chemically functionalised materials with functional groups on their surfaces which are not easily derived from gaseous feedstocks. The method according to the present invention can even be used with salt solutions in order to chemically functionalise materials with functionalities derived from salts and also means that liquids with high viscosities can be used, which would not be suitable for use with a bubbler system.

Thirdly, the method according to the present invention does not rely on deposition of material from the electrode itself, as taught in WO 2015/145172. There is no requirement for contact between electrodes and sample, nor the need to sacrifice electrode material to achieve surface decoration. This gives far greater flexibility in terms of the configuration used to achieve and maintain a glow discharge plasma (for example, it is compatible with the use of electrodes sheathed in an insulative material), and in terms of the type and level of metal decoration which can be achieved. Importantly, it also allows for the decoration of the sample surface with non-conductive solid materials, which is not possible according to the method taught in WO 2015/145172.

The delivery of gaseous plasma forming feedstock and reagent occurs simultaneously. However, it is also possible to have periods in which only the gaseous plasma forming feedstock or reagent occurs. For example, in some embodiments the method involves first establishing a glow discharge plasma from the gaseous plasma forming feedstock, and then delivering the reagent into the treatment vessel.

Suitably, the reagent is delivered into the glow discharge plasma. In this way, the reagent can be activated by the glow discharge plasma upon entry to the treatment vessel, before it makes contact with the sample.

The reagent may be delivered directly into the treatment vessel. This may be referred to as “direct injection”.

The reagent may be combined with a gas (e.g. entrained by a gas) subsequent to the reagent dosing controller before delivery into the treatment vessel. In particular, the liquid or solid reagent may be supplied into the gas supply line, and delivered into the treatment vessel via the gas supply line. Suitably, the point at which the liquid or solid reagent enters the gas supply line is after (“downstream” of) both the gas flow controller and reagent dosing controller, since this allows independent control of the rate of delivery of the gas and reagent and minimises the opportunities for clogging/degradation of the controllers.

The reagent may be activated in the treatment vessel, for example, the reagent may become activated by the glow discharge plasma and/or by the low pressure present in the treatment vessel.

Activation of the reagent may involve ionisation of the reagent upon contact with the glow discharge plasma. Alternatively, activation of the reagent may involve a chemical transformation, for example, breakdown of the reagent into different chemicals or reaction of the reagent with another species (e.g. species created in the glow discharge plasma by the gaseous plasma feedstock).

### Reagent Dosing Controller

The reagent dosing controller according to the present invention controls the feed/flow of liquid or solid reagents from a reservoir into the treatment vessel during the course of treatment.

The reagent dosing controller may be a mechanical or motorised injection system.

The reagent dosing controller may be a pump. The use of a pump as the reagent dosing controller is especially preferred when the reagent is a liquid.

The pump may be, for example, a positive displacement pump, a dynamic pump, or a gravity-fed pump.

Optionally, the pump is a dynamic pump. For example, the pump may be a centrifugal pump.

Preferably, the reagent dosing controller is a positive displacement pump. The positive displacement pump may be a reciprocating pump, such as a piston pump, plunger pump, or diaphragm pump. Alternatively, the positive displacement pump may be a rotary pump, such as a gear pump, a screw pump, a lobe pump, an impeller pump, or a rotary vein pump.

The positive displacement pump may take the form of a piston pump or a plunger pump. In such a system, the reservoir of liquid or solid reagent is held in a chamber and forced through an outlet. Depression of the plunger/piston causes ejection of the reagent from the chamber through the outlet. The pump includes a pump actuator which holds the plunger/piston in position. The pump actuator prevents unwanted movement of the plunger/piston, for example, movement which might otherwise occur due to pressure differentials between the external environment of the plunger (e.g. atmosphere) and internal pressure of the system (e.g. vacuum in the treatment vessel, pressure created by the gaseous plasma feedstock).

The pump may be, for example, a syringe pump, such as an Aladdin syringe pump. Preferably, such a system incorporates a removable syringe connected to the pump actuator as discussed above. Advantageously, having a removable syringe can greatly simplify loading of reagent, and subsequent cleaning of the syringe and apparatus more generally. Suitable syringes are widely available as a standard component, are cheap, and are easily disposed of and replaced. This means that, for example, instead of cleaning the system between different treatments a syringe can be disposed of and replaced with another syringe, thus minimising the risk of contamination between samples. Such a system also facilitates rapid switching between different syringes during treatment, or between treatment steps.

Alternatively, the positive displacement pump may be a peristaltic pump, such as a pericyclic pump.

Preferably, the positive displacement pump may be a piston or peristaltic pump.

Suitably, the liquid reagent is stored in a holding tank/container in fluid communication with said pump.

The reagent dosing controller may be a conveyor system. The use of a conveyor system as the reagent dosing controller is especially preferred when the reagent is a solid.

The conveyor system may be a screw conveyor (alternatively referred to as an auger conveyor, screw feeder, or auger feeder), a belt conveyor, a bucket conveyor, or a vibrating conveyor.

Generally, in such systems the reservoir of liquid or solid is held in a hopper, and the conveyor system delivers reagent from the hopper to the treatment vessel.

In instances where the reagent is a solid taking the form of particles/pellets, the reagent dosing controller may be a pellet gate system. Such systems include a valve which opens and closes to control the rate of delivery of the particles/pellets. For example, such a system may include a valve which controls the pneumatic discharge of pellets/particles into the treatment vessel.

Suitably, the reagent dosing controller is adjustable to allow the rate of delivery of the reagent to be varied. Preferably, the reagent dosing controller is continuously adjustable. For example, the reagent dosing controller may include a flow meter when delivering a liquid reagent.

Alternatively, the rate of addition of the reagent may be pre-set at the beginning of the reaction or treatment step.

For example, in instances where the reagent dosing controller is a syringe pump operated by a pump actuator, the pump actuator may be adjustable to vary the rate of depression of the syringe piston.

Similarly, in instances where the reagent dosing controller is a conveyor, the system may have a control system for adjusting the rate of the conveyor.

A suitable rate of addition of the reagent will be determined by a multitude of factors, such as the pressure within the treatment vessel, the size of the treatment vessel and the mass of sample being treated. Generally, when larger masses of sample are being treated a faster rate of addition will be required and more reagent is required overall.

As an example, the method may involve delivering 1 to 100 g of reagent per kilogram of sample, such as from about 5 to about 30 g of reagent per kilogram of sample, more preferably about 10 g of reagent per kilogram of sample.

The rate of delivery of reagent may be, for example, about 1 to 20 g/minute, 1 to 10 g/minute, or about 1 to 5 g/minute.

The rate of delivery of reagent may be constant. Alternatively, the rate may be adjusted during the course of treatment. For example, the method may involve reducing the rate of delivery during the course of treatment, either continuously (e.g. according to a linear gradient) or stepwise. Similarly, the method may involve increasing the rate of delivery during the course of treatment, either continuously (e.g. according to a linear gradient) or stepwise.

### Gas Flow Controller

The gas flow controller may take the form of a gas regulator, mass stream or a mass flow controller which controls the flow of gaseous plasma forming feedstock into the treatment vessel.

### Plasma Formation

The plasma treatment is by means of low-pressure plasma of the “glow discharge” type, usually using low-frequency RF (less than 100 kHz) AC. Most preferably, the plasma is formed at a frequency below 100 kHz, such as between 25-35 kHz.

To generate low-pressure or glow plasma, the treatment vessel needs to be evacuated. Thus, suitably, the method comprises reducing pressure in the treatment vessel prior to delivery of the gaseous plasma forming feedstock.

The pressure in the treatment vessel is desirably less than 1000 Pa, more preferably less than 500 Pa, less than 300 Pa and most preferably less than 200 Pa or less than 100 Pa. For the treatment of carbon nanotubes (CNT's) and graphitic particles especially, pressures in the range 0.05-5 mbar (5-500 Pa) are usually suitable, more preferably 0.1-2 mbar (10-200 Pa).

In addition, the treatment vessel is generally evacuated during the delivery of the gaseous plasma forming feedstock and reagent, to avoid unwanted build-up of pressure and to facilitate removal of waste.

Evacuation of the treatment vessel during delivery of the gaseous plasma forming feedstock and reagent determines the residence times of the gaseous plasma forming feedstock and the reagents in the treatment vessel. If evacuation is fast, the reagents may have little time to contact the sample. If the evacuation is slow, pressure in the treatment vessel may build up to a level which does not support stable glow discharge plasma, e.g. with the formation of unwanted arcing events between electrodes.

Thus, to control pressures within the treatment vessel the apparatus preferably comprises a vacuum system incorporating a vacuum pump and a vacuum pump valve to control the level of vacuum applied by the vacuum pump. The vacuum pump valve may be, for example, a vacuum shut-off or throttle valve, which when closed acts to limit the effect of the vacuum pump.

Preferably, the apparatus includes a pressure feedback system which obtains pressure data from the treatment vessel (e.g. from a pressure sensor mounted in the treatment vessel) and actuates the vacuum pump valve based on the pressure data. The pressure feedback system may take the form of a programmable logic controller (PLC), which monitors the pressure inside the treatment vessel and controls the throttle valve, to control the rate at which the gas is removed from the treatment vessel. Suitable examples of PLCs include Guardlogix from Allen-Bradley or F-series PLCs from Siemens.

The vacuum pump valve may be set to maintain the pressure inside the treatment vessel at a target value, whereby when the pressure is too high the vacuum pump valve allows excess gas to be removed from the treatment vessel, causing the pressure to decrease until it returns to the target value.

The vacuum pump valve is not particularly limited and may include any mechanism that controls the flow of gas and thus controls the pressure in the treatment vessel. For example, the vacuum pump valve may be a plunger valve, a butterfly valve, an electric valve or a solenoid valve.

The apparatus may also comprise a filter for avoiding debris from entering the vacuum pump. The filter should be selected as regards its pore size to retain particles of interest and as regards its material to withstand the processing conditions and to avoid undesirable chemical or physical contamination of the product, depending on the intended use thereof. For the retention of particles, HEPA filters, ceramic, glass or sintered filters may be suitable depending on the size of the particles.

### Treatment Apparatus

The glow discharge plasma may be generated by supplying microwave radiation to the treatment vessel or, more preferably, by applying a voltage between two electrodes.

For example, the treatment apparatus may comprise an electrode and a counter-electrode, wherein the electrode is connected to a power supply. In such instances, the method of the invention may involve applying a voltage between the electrode and counter-electrode to cause formation of the glow discharge plasma within the treatment vessel.

In preferred implementations, the treatment apparatus comprises at least one electrode within the treatment vessel. In such implementations, the counter-electrode may be outside of the treatment vessel. Alternatively, the treatment vessel may be or comprise the counter-electrode. For example, a/the wall of the treatment vessel may serve as the counter-electrode.

Preferably, the method involves agitating the sample within the treatment vessel during treatment, since this can improve the homogeneity of treatment and permit larger quantities of sample to be treated. This may be through vibrating/shaking the sample (for example, by an oscillating or reciprocating motion of the treatment vessel) or through applying rotational motion to the treatment vessel. Alternatively, or additionally lifters may be used inside the vessel to agitate the sample.

In particularly preferred implementations, the method involves rotating the treatment vessel to cause agitation of the sample during treatment. To achieve this, the treatment vessel may take the form of a treatment drum (a rotatable drum). The outer wall of the drum is desirably cylindrical, or circular in cross-section. The drum may be capped by end plates, front and back. The end plates may be integral to the outer wall of the drum. Alternatively, one or both of the end plates may be removable, so as to serve as a lid or cover for the drum.

Preferably, the treatment drum is mounted on and rotatable about an axle.

Suitably, the axle remains stationary during operation and the treatment drum is driven around the axle. In such instances, the axle preferably comprises or serves as the electrode. Advantageously, this implementation simplifies electrical connections, since it is possible to connect the electrode to its power supply without having to take into account relative rotation of the electrode and power supply.

The treatment vessel includes one or more gas ports connected to the gas supply line for delivery of the gaseous plasma forming feedstock into the treatment vessel.

The gas port(s) may include a filter to prevent entry of debris from the treatment vessel.

The gas port(s) may be provided in a wall of the treatment vessel. More preferably, the treatment apparatus includes at least one electrode within the treatment vessel with one or more gas ports provided on the electrode. For example, the gas port(s) may take the form of a hole at the end of the electrode and/or a hole provided along the length of the electrode. Such configurations are especially useful, since they provide the gaseous plasma forming feedstock at the point at which it is required for plasma formation.

The treatment vessel also includes one or more reagent ports for delivery of the reagent into the treatment vessel.

The reagent ports may include a filter to prevent entry of debris from the treatment vessel.

The reagent port(s) may include a dispersing element, to help direct or disperse the reagent as it exits the port. The dispersing element may be, for example, a diffuser, sprayer or fan. These can be used to distribute/spread a liquid sample within the treatment vessel, which can be useful for achieving uniform treatment. Alternatively, or additionally, the dispersing element may be a nozzle. Such a nozzle can be used to direct the reagent to the region of the treatment vessel in which it is required, for example, into the region in which glow discharge plasma is being generated.

The reagent port(s) may be provided in a wall of the treatment vessel. More preferably, the treatment apparatus includes at least one electrode within the treatment vessel, and the reagent port for delivery of the reagent is provided on the electrode. For example, the reagent port may take the form of a hole at the end of the electrode and/or holes provided along the length of the electrode. Such configurations are especially useful, since they deliver the reagent into the glow discharge plasma.

In an especially preferred configuration, the treatment apparatus includes at least one electrode within the treatment vessel, and the gaseous plasma forming feedstock and reagent are delivered through the same port. For example, the electrode may have a hole at its end and/or holes provided along the length of the electrode through which the gaseous plasma forming feedstock and reagent are both delivered.

In instances in which the treatment vessel is a treatment drum which rotates about a stationary axle, the one or more gas/reagent ports are preferably provided on the axle. Advantageously, such an implementation simplifies delivery of the plasma forming gaseous feedstock and reagent, since it is not necessary to take into account rotation of the gas/reagent supply lines during treatment.

In especially preferred implementations, the treatment vessel is a treatment drum which rotates about a stationary axle, the axle comprises or serves as the electrode, and the one or more gas/reagent ports are provided on the axle. In such implementations, the one or more gas/reagent ports are preferably provided on the electrode in the manner discussed above.

In instances where the treatment vessel is rotated during use, the rotation may be continuous (for example, as described in WO 2012/076853). Alternatively, the treatment vessel is rotated in a first direction, and then rotated in the opposite direction about the same axis. For example, the treatment vessel is preferably rotated back and forth through an incomplete turn, which is referred to herein as “rocking”. For example, the treatment vessel may be rotated through a total angle of no more than 180°, no more than 120°, or no more than 90° (the “total angle” corresponding to the full arc subscribed by a set point on the treatment vessel). Preferably, the treatment vessel is rotated through an angle of no more than ±220°, no more than ±180°, no more than ±120°, no more than ±90°, no more than ±80°, no more than ±70°, no more than ±60°, no more than ±50°, no more than ±45° or no more than ±30°, measured relative to the starting position of the treatment vessel. In such instances, when the sample in the treatment vessel is a particulate sample, the rocking motion can cause “folding” of the particles over each other, thereby incorporating the glow discharge plasma into the sample.

The lower limit for the amount through which the vessel is rotated may be, for example, at least ±10°, at least ±20°, at least ±30°, or at least ±45°.

The treatment vessel may be rotated (or rocked) at a frequency of at least 1/12 Hz, at least ⅙ Hz, at least ¼ Hz or at least ⅓ Hz. The maximum may be, for example, 1 Hz or 2 Hz. When the vessel is rocked, this corresponds to the frequency with which the rocking motion is completed per second. When the treatment vessel is rotated continuously, these figures can be expressed as revolutions per minute (rpm) corresponding to at least 5 rpm, at least 10 rpm, at least 15 rpm, at least 20 rpm, up to a maximum of for example 60 rpm or 120 rpm.

Preferably, the treatment vessel is rotated through an angle of ±90° at a frequency of from ⅙ to ½ Hz.

Rotating the treatment vessel alternately between a first direction and its opposite direction can lead to a number of advantages over rotating the vessel continuously in one direction.

In particular, this method of agitation can significantly simplify design of the apparatus, and delivery of components into the treatment vessel.

For example, continuously rotating the treatment vessel in a given direction presents less design flexibility in terms of how the gaseous plasma forming feedstock and reagent are delivered into the treatment vessel. For example, if gas/reagent/electrical supply lines are fixed to the treatment vessel, these may become unusable due to twisting/tangling/spooling of the lines during continuous rotation, but remain usable if the vessel is only rocked. In addition, rocking the treatment vessel back and forth, instead of through complete turns, reduces the risk of the sample falling through the central part of the treatment vessel, which may contain sensitive equipment, such as electrodes and ports.

Optionally, the treatment vessel may comprise multiple electrically conductive solid contact bodies or contact formations as taught in WO 2012/076853. These solid contact bodies or contact formations are used to agitate the sample during use. In addition, without being bound by theory, it is believed that glow discharge plasma can form around the solid contact bodies or contact formations during treatment to boost the level of treatment achieved.

During the course of treatment, the apparatus and sample may heat up. This heating may be caused by resistive heating of the electrical components of the apparatus, in particular, heat generated by the electrode. In instances where the sample is agitated during use, heating may also arise through friction. Such heating may lead to degradation of the material being treated (for example, stripping away surface functionalisation) and may damage the plasma treatment apparatus. For example, plastic materials may degrade/melt at temperatures of about 100° C. and graphene is damaged at temperatures above 400° C.

In other instances, heating of the treatment apparatus can be advantageous. For example, it can limit or prevent condensation of unwanted liquids within the treatment vessel, and can also help to drive desired treatment steps, such as functionalisation.

Accordingly, in the present invention, the treatment vessel is optionally provided with a temperature control system, for cooling and/or heating the treatment vessel in use.

Suitably, the temperature control system is for cooling and/or heating the walls of the treatment vessel—that is, the surface which contacts the sample in use. To achieve this the temperature control system may be mounted on or in the exterior walls of the treatment vessel.

The temperature control system may be an electronic heating/cooling system, such as a system based on resistive heating or thermoelectric (Peltier) heating. Additionally, or alternatively, the temperature control system may be a fluid-based heating/cooling system, preferably a liquid-based heat transfer system, such as a water- or oil-based heat transfer system. When an oil-based heat transfer system is used the temperature of the treatment vessel may be determined by measuring the inlet temperature of the oil and using a formula to determine the temperature of the treatment vessel based on the inlet temperature of the oil.

The temperature controlled treatment vessel may be held at a constant temperature such as e.g. from about −20° C. to about 120° C., or from about 10° C. to about 80° C., or from about 20° C. to about 50° C. or about room temperature (25° C.). The temperature used may be tailored to the treatment gas/plasma forming feedstock being used for glow plasma formation, for example treatment with oxygen (O 2) gas may be carried out a low temperatures of from about −20° C. to about 0° C.; whereas treatment with ammonia (NH 3) may be carried out at higher temperatures such as from about 60° C. to about 120° C.

When the temperature is controlled by a fluid-based heating/cooling system, the temperatures discussed above correspond to the temperature of the heating/cooling fluid immediately before entering the treatment vessel. More generally, the temperature may be determined based on the pressure change within the treatment vessel, or based on the difference between the flow rate ratios of feedstock entering the treatment vessel and feedstock leaving the treatment vessel required to maintain constant pressure within the treatment vessel.

In instances where the treatment vessel is rotated (continuously or partially) the design of the temperature control system is not straightforward. In particular, positioning the temperature control system internally within the treatment vessel can lead to interference between this system and the sample (and vice versa), as well as interference with plasma formation. Positioning the temperature control system outside the treatment vessel avoids interfering with the sample and plasma, but can instead interfere with the mechanics required to rotate the vessel. For example, mounting the temperature control system at only a single location can lead to the vessel becoming unbalanced during rotation, putting strain on the plasma apparatus during rotation. Furthermore, the vessel is generally mounted within a fixed housing via rollers, which support the vessel in use, and the provision of temperature control components on the outside of the treatment vessel may prevent the vessel from rotating over the rollers, or cause bumping of the vessel over the rollers.

Thus, in instances where the method involves rotating (continuously or partially) the treatment vessel around an axis which extends through a back end and a front end of the treatment vessel, the temperature control system preferably comprises at least one vessel heat-transfer line mounted on or in the exterior wall of the treatment vessel, and a heat-transfer input line connected to the at least one vessel heat-transfer line at said back end or front end of the treatment vessel. (For the avoidance of doubt, the word “line” is intended to cover both fluid and electrical systems, for example, to refer to both tubing and/or an electrical wire). The heat-transfer input line is connected to a heat supply (such as an oil or water heater, or a source of electricity in the case of an electric heating system). Preferably, the connection between the at least one vessel heat-transfer line and the heat-transfer input line occurs at (or close to) the axis of rotation of the treatment vessel, so as to prevent the point of connection moving in an arc or a circle as the treatment vessel rotates.

According to this implementation, the vessel heat-transfer lines can be designed and configured so as to permit efficient rotation of the barrel. Furthermore, positioning the input line at the back end or front end, instead of around the rotating circumference of the treatment vessel, means that the heat-transfer feed can be positioned away from any rollers which support the treatment vessel, and in such a way as to prevent the system from becoming unbalanced.

Optionally, the at least one vessel heat-transfer line is connected to the heat-transfer feed line through a rotating coupler, which allows the vessel heat-transfer line and heat-transfer feed to rotate relative to one another. This limits or prevents winding of the feed line and vessel heat-transfer line. Preferably, the at least one vessel heat-transfer line is connected to the heat-transfer feed line through a rotating coupler aligned with the axis of rotation of the treatment vessel, since this configuration can completely eliminate any winding of the vessel heat-transfer line(s) and heat-transfer feed line.

In some implementations, it may be possible to effectively heat the treatment vessel solely through the heat-transfer input line. For example, a heating/cooling fluid may undergo repeated cycles of being flowed into the at least one vessel heat-transfer line, and then removed from the at least one vessel heat-transfer line through the heat-transfer input line.

However, in other implementations it is advantageous to connect the at least one vessel heat-transfer line to both a heat-transfer input line and a heat-transfer output line, to permit the continuous flow of heating/cooling fluid or electricity.

In one implementation, the connection between the vessel heat-transfer line and heat-transfer input line occurs at one end of the treatment vessel, and the connection between the vessel heat-transfer line and heat-transfer output line occurs at the other end of the treatment vessel. In such instances, the vessel heat-transfer line may extend from one end of the treatment vessel to the other end, for example, in a straight line or by coiling around the treatment vessel, e.g. in the form of a helix.

In these embodiments, it is advantageous for the connection between the at least one vessel heat-transfer line and the heat-transfer input line to occur at (or close to) the axis of rotation on one side of the treatment vessel, and the connection between the at least one vessel heat-transfer line and the heat-transfer out line to occur at (or close to) the axis of rotation at the other side of the treatment vessel. As set out above, this arrangement minimises movement of the connections in an arc or a circle as the treatment vessel rotates. When rotating couplers are used for each connection in this arrangement, winding of the temperature control system components can be avoided altogether.

Preferably, connections to the heat-transfer input line and heat-transfer output line occur at the same end of the vessel. This may be achieved, for example, by providing the at least one vessel heat-transfer line with one or more bends. For example, the at least one vessel heat-transfer line may pass back and forth from one end of the vessel to the other in the form of a zigzag, or with U-shaped bends, with points for connecting to the heat-transfer input line and heat-transfer output line provided at the same end of the treatment vessel.

In these embodiments, it is again advantageous for the connection between the at least one vessel heat-transfer line and both the heat-transfer input line and heat-transfer output line to occur at (or close to) the axis of rotation, so to minimise movement of the connections in an arc or a circle as the treatment vessel rotates. This may be achieved, for example, by having the connection points at different points along the axis of rotation, i.e. with one connection point positioned relatively further forward than the other connection point. Again, when rotating couplers are used for each connection in this arrangement, winding of the temperature control system components can be avoided altogether.

Suitably, the treatment vessel takes the form of a drum having a side-wall and front and back walls, with the drum rotating about an axis passing through the front and back walls. In such instances, the at least one vessel heat-transfer line extends around the side-wall of the drum, and the heat-transfer input line is preferably coupled to the vessel heat-transfer line(s) through a connection at the front or back wall.

As noted above, in many instances it is useful to use rotating couplers to connect the vessel heat-transfer line(s) to the heat-transfer input line. However, in instances where the treatment vessel is rocked back and forth, the temperature control system is not subject to continued winding, and thus the rotatable coupler can be dispensed with. Thus, in an advantageous embodiment, the methods of treating a sample discussed above involves agitating the sample by rocking the treatment vessel back and forth, wherein the treatment vessel is provided with a temperature control system. In such instances, the temperature control system may again include at least one vessel heat-transfer line provided in or on the treatment vessel without the use of a rotating coupler, since the amount of twisting and/or winding between the heatable elements and the stationary heat supply element is limited. In this implementation, the vessel heat-transfer line and heat-transfer input line can be separate parts connected through a (non-rotatable) coupler, or can be integral to one another (for example, a continuous tube or wiring). This is particularly advantageous from an economic perspective, as rotatable couplers can make the temperature control system more expensive and more complicated. Additionally, from a safety perspective, if an oil heater line is being used to control the temperature of the treatment vessel, it is advantageous to avoid using a rotatable coupler. This is because using a rotatable coupler carries the risk of hot oil spilling out of the coupler if the seal is not completely tight. Loosening of a rotatable coupler may occur during normal operation of a rotatable coupler.

### Advanced Generator System/Multi-Transformer System

As discussed above, in a preferred implementation, the treatment apparatus comprises an electrode and a counter-electrode, wherein the electrode is connected to a power supply. In such instances, the method of the invention may involve applying a voltage between the electrode and the counter electrode to cause formation of the glow discharge plasma within the treatment vessel.

Preferably, the power supply comprises one or more transformers, having a first transformer setting and a second transformer setting. In such instances, the method of the invention may further comprise at least a first and a second treatment step,
the first treatment step involving treating the sample in a glow discharge plasma formed within the treatment vessel by applying an electric field between the electrode and counter-electrode at a first transformer setting;
the second treatment step involving treating the sample in a glow discharge plasma formed within the treatment vessel by applying an electric field between the electrode and counter-electrode at a second transformer setting.

The gaseous plasma forming feedstock and reagent may be delivered to the treatment vessel at any point during either the first or second treatment steps.

Advantageously, switching between transformer settings alters the electric field between the electrode and counter-electrode, and hence can be used to change the nature of the plasma. This means that the transformer settings can be tailored to the particular conditions present during the first and second treatment steps, so as to form stable plasma at a desired power.

The method is especially useful when the gaseous plasma forming feedstock is changed from the first and second treatment steps. Specifically, the transformer settings can be chosen to both generate and maintain a stable plasma using a wide range of different feedstocks. This opens up the possibility of treating with gaseous plasma forming feedstocks having different properties in a single treatment run, expanding the range of treatments possible. For example, the method may involve a first treatment step using a gas which has a relatively low dielectric strength and a second treatment step using a gas which has a relatively high dielectric strength.

Additionally, or alternatively this method opens up the possibility of treating the sample with different reagents during the first and second treatment steps. Specifically, the transformer settings can be chosen to both generate and maintain a stable plasma using a wide range of different reagents. This opens up the possibility of treating with different reagents in a single treatment run.

The method is especially useful for functionalisation of particles, since the method may be used to achieve multi-step functionalisation processes.

More generally, this method is useful when there is a change in the type of treatment being applied and/or the treatment conditions between the first and second treatment step, such as a change in the pressure in the treatment vessel.

Being able to change the transformer setting between treatment steps minimises and can potentially eliminate the occurrence of arcs during treatment, which helps to prevent damage to the apparatus.

Suitably, switching between the first and second transformer settings occurs during operation of the apparatus. By “during operation of the apparatus” we mean that the apparatus is not shut down during switching between transformer settings. In other words, the method for treating a sample is a continuous process. This allows the sample to be retained in the treatment vessel between the first and second treatment steps.

The first and second transformer settings may have voltage ratios (defined as the primary voltage rating divided by the secondary voltage rating at no load) of, for example, 0.5 or less, or less, 0.4 or less, 0.35 or less, 0.3 or less, 0.25 or less, 0.2 or less, 0.15 or less, 0.1 or less, 0.05 or less, 0.025 or less, or 0.01 or less.

Preferably, the first and second transformer settings have different voltage ratios. Thus, the first and second transformer settings may correspond to transformer settings having different secondary voltage ratings. For example, the difference between the first and second transformer voltage ratios may be at least 0.01, at least 0.025, at least 0.05, at least 0.1, at least at least 0.2, at least 0.25, at least 0.3, at least 0.35, at least 0.4, at least 0.45, or at least 0.5. In this way, for a given input voltage, switching between the first and second transformer settings will lead to a different voltage being developed at the electrode.

The secondary voltage ratings of the first and second transformer settings may be, for example, 100 V or more, 200 V or more, 300 V or more, 400 V or more, 500 V or more, 750 V or more, 1.0 kV or more, 1.5 kV or more, 2.0 kV or more, 2.5 kV or more, 3.0 kV or more, 5.0 kV or more, kV or more or 15.0 kV or more. The first and second transformer settings may correspond to transformer settings having different secondary voltage ratings. For example, the first transformer setting may be a relatively lower secondary voltage rating and the second transformer setting may be a relatively higher secondary voltage rating, or vice versa.

The difference between the secondary voltage rating of the first and second transformer settings may be at least 100 V, at least 200 V, at least 300 V, at least 400 V, at least 500 V, at least 750 V, at least 1.0 kV, at least 1.5 kV, at least 2.0 kV, at least 2.5 kV, at least 3.0 kV, at least 4.0 kV, at least 5.0 kV, or at least 10 kV. The upper limit for the difference between the secondary voltage rating of the first and second transformer settings may be, for example, 5.0 kV, 3.0 kV, 2.5 kV, 2.0 kV, 1.5 kV, 1.0 kV or 500 V. For example, the difference between the secondary voltage rating of the first and second transformer settings may be between 100 V to 3.0 kV, 100 V to 2.0 kV, or 500 V to 2.0 kV.

The power supplied by the power supply may remain the same during the first treatment step and second treatment step. Alternatively, the method may involve changing the power supplied by the power supply between the first treatment step and the second treatment step. To this end, the method optionally includes the step of the user selecting the desired power (Watts) to be supplied to the electrode during the first and/or second treatment step. For example, the first treatment step may be a relatively low power “gentle” treatment (say, at 70 W power) and the second treatment step may be a relatively higher power “aggressive” treatment (say, at 2000 W).

The present inventors have discovered that the peak voltage measured at the electrode during maintenance of the glow discharge plasma at the desired power level (i.e. the voltage developed upon application of a load), expressed as a percentage of the secondary voltage rating at no load (i.e. the nameplate secondary voltage rating), provides a good measure of the performance of the transformer setting. This measure is referred to herein as the “voltage rating percentage”. Specifically, they have found that when the voltage rating percentage required to achieve the desired power level is of the order of 80-95%, the apparatus forms an even, stable plasma with minimal or no formation of arcs. In contrast, voltage rating percentages at ˜100% lead to flickering of the plasma, as the power supply struggles to achieve the desired power at the electrode. Similarly, voltage rating percentages of below 80% also cause the power supply to have difficulty in supplying the required power levels. In certain instances, the power supply may decrease the frequency of the supplied AC power supply in order to supply the required power level, which leads to further inefficiency in the voltage conversion provided by the transformer setting.

The first and second transformer settings may have volt-ampere (kVA) output power ratings of, for example, at least 0.2 kVA, at least 0.5 kVA, at least 1.0 kVA, at least 1.5 kVA, at least 2.0 kVA, at least 2.5 kVA, at least 3.0 kVA, at least 4.0 kVA, at least 5.0 kVA, at least 8.0 kVA, at least 10 kVA, at least 15 kVA, at least 25 kVA, at least 50 kVA, at least 100 kVA, at least 250 kVA, or at least 500 kVA.

The first and second transformer settings may correspond to transformer settings having different volt-ampere (kVA) output power ratings. For example, the first transformer setting may be a relatively lower kVA output power rating and the second transformer setting may be a relatively higher kVA output power rating. The difference between the kVA output power ratings of the first and second transformer settings may be, for example, at least 0.2 kVA, at least 0.5 kVA, at least 1.0 kVA, at least 1.5 kVA, at least 2.0 kVA, at least 2.5 kVA, at least 3.0 kVA, at least 4.0 kVA, at least 5.0 kVA, at least 8.0 kVA, at least 10 kVA, at least 15 kVA, at least 25 kVA, at least 50 kVA, at least 100 kVA, or at least 250 kVA.

Preferably, switching between the first and second transformer settings occurs according to a pre-set program. For example, the program may be configured to switch between the first and second transformers in response to processing parameters, such as elapsed time, pressure in the treatment vessel or, preferably, in response to a change in the plasma-forming feedstock or reagent being delivered. Preferably, the switching between the first and second transformer settings is automated.

The first and second transformer settings may correspond to the use of the power supply with first and second transformers respectively. In such instances, the first treatment step involves generating a glow discharge plasma using a first transformer, and the second treatment step involves generating a glow discharge plasma using a second transformer, wherein the first transformer and second transformer have different characteristics, such as a different voltage ratio, secondary voltage and/or volt-ampere power output rating.

For example, the secondary voltage rating of the first transformer may be lower than the secondary voltage rating of the second transformer. Alternatively, the secondary voltage rating of the first transformer may be higher than the secondary voltage rating of the second transformer. The first and second transformers may have any of the voltage ratios, secondary voltage ratings and volt-ampere power ratings specified above.

Alternatively, the first and second transformer settings may correspond to switching between different settings on a single transformer. For example, the settings may correspond to switching between taps on a single transformer. Such a transformer may have, for example, 2, 3, 4, 5, 6, 7, 8, 9, 10, 15, or 20 taps to produce different voltage ratio ratings. For example, the transformer may have 2, 3, 4, 5, 6, 7, 8, 9, 10, 15, or 20 taps on the secondary coil in order to produce different secondary voltages.

For the avoidance of doubt, the terms “first” and “second” used in relation to the treatment steps indicate the sequence of those steps relative to one another, and do not exclude the possibility of other steps taking place before, between, and/or after. There may be no intervening steps between the first and second treatment steps.

### Power Levels

The method for treating a sample is by means of low-pressure plasma of the “glow discharge” type, usually using low-frequency RF (less than 100 kHz) AC. Most preferably, the plasma is formed at a frequency below 100 kHz, such as between 25-35 kHz. As discussed above, in a preferred implementation, the treatment apparatus comprises an electrode and a counter-electrode. In such instances, the method of the invention may involve applying a voltage between the electrode and the counter electrode to cause formation of the glow discharge plasma within the treatment vessel.

Optionally, the power supplied from the power supply during the method according to the present invention is modulated periodically between a higher power level and a lower (or no) power level. In particular, the present inventors have found that modulating the power levels so that high power levels are only used for a short period, boosts the level of sample treatment, whilst reducing the risk of arcing compared to running continuously at the same power level. This is particularly useful, when treating materials that are conductive or require high powers in order to effect treatment (e.g. functionalisation). Without wishing to be bound by any theory, it is believed that modulating the power levels reduces the chance of the plasma stabilising, meaning that with each modulation potential arcing sites are eliminated.

This modulation of power levels during the method for treating a sample should be distinguished from switching between a first transformer setting and a second transformer setting between different treatment steps. The former occurs at the same transformer setting. In addition, the former necessitates a change in the power supplied to the electrode(s), whereas the latter does not.

The power may be modulated between the higher and lower levels periodically according to a set pattern. The pattern may have any suitable waveform, for example, a sine wave, a square wave, a triangular wave or a saw tooth wave. The frequency at which the pattern repeats may be at least 1/60 Hz (one cycle per minute), at least 1/30 Hz, at least 1/10 Hz, at least 1 Hz, at least 2 Hz, at least 10 Hz, at least 20 Hz, at least 100 Hz, or at least 500 Hz. The frequency of repetition may optionally be less than 1000 Hz, or less than 500 Hz such as for example, from 1/60 Hz to 100 Hz.

The power (in Watts) of the lower power level may be no more than 90% of the higher power level, no more than 80% of the higher power level, no more than 70% of the higher power level, no more than 60% of the higher power level, or no more than 50% of the higher power level.

The lower power level may be at least 10%, at least 20%, at least 30%, at least 40% or at least 50% of the higher power level.

In instances where the power is modulated periodically according to a set pattern, the lower power level may correspond to supplying no power. In other words, modulation of the power level may involve switching between >0 Watts and 0 Watts.

The higher and lower power levels may vary within ±10%, ±20%, ±30%, or ±40% of the mean power level (the mean calculated as half of the sum of the maximum and minimum power levels).

In instances where the set pattern is a square waveform, the time spent at the higher power level may be equal to that spent at the lower power level. Alternatively, for square waveforms the ratio of time spent at the higher power level compared to the lower power level may be, no more than 0.8, no more than 0.6, no more than 0.4, no more than 0.3, no more than 0.2, or no more than 0.1, when expressed as a fraction (that is, time spent at the higher power level divided by time spent at the lower power level). Alternatively, the ratio of time spent at the higher power level compared to the lower power level may be, at least 1.2, at least 1.5, at least 2.0, at least 3.0, at least 4.0, or at least 5.0.

The higher and lower power levels are determined based on the values measured directly from the power supply.

The power may be modulated in this manner for the whole of the method of treatment; alternatively, the power may be modulated for only part of the method of treatment. For example, the power may be modulated at the beginning of the method of treatment, in order to functionalise a material at higher power, but then treated at a different power level at the end of the method.

Preferably, the power is modulated during the method of treatment between >0 W (the higher power level) and 0 W (lower power level) at a frequency of from 500 Hz to 1000 Hz. Preferably, the ratio of time spent at the higher power level compared to the lower power level is at least 1.

For samples comprising components that are larger than 1 mm in size it is preferable to modulate the power according to a set pattern at a frequency of from 1/60 Hz to 1 Hz. In contrast, for samples comprising components that are smaller than 1 μm it is preferable to modulate the power according to a set pattern at a frequency of from 1 Hz to 1000 Hz. A faster modulation is preferred as the particle size decreases, because smaller particles generally lead to an increased risk of arc formation.

### Pressure Stabilisation Devices/Filter System

In the methods of the invention which involve treatment of samples comprising small discrete parts, it is necessary to design the treatment vessel to retain the sample during treatment. This is particularly important for the treatment of particulate material, especially microparticles or nanoparticles. In the present invention, this is preferably achieved by having a solid treatment vessel (i.e. a treatment vessel having impermeable walls) provided with at least one vessel filter.

The vessel filter should be selected as regards its pore size to retain the sample in question, and as regards its material to withstand the processing conditions and to avoid undesirable chemical or physical contamination of the product, depending on the intended use thereof. For the retention of particles, HEPA filters, ceramic, glass or sintered filters may be suitable depending on the size of the particles. The evacuation port may be in a main vessel wall or in a lid or cover.

Generally, during the course of glow-plasma treatment a plasma forming feedstock is continuously fed into the treatment vessel and waste feedstock is exhausted through the vessel filter(s). However, over the course of the plasma treatment the filters can become blocked, due to accumulation of a particulate sample intentionally introduced to the treatment vessel or by detritus formed during treatment. This blockage is a particular concern when the sample is agitated during use, because particulate material can be lifted up or generally ride up the side of the treatment vessel, so as to be at the level of the vessel filter.

Blockage of the vessel filter(s) interferes with removing the waste feedstock from the treatment vessel, and leads to pressure build up. The increase in pressure affects the nature of the plasma formed, and the propensity to form arcs. At a certain point the increase in pressure will prevent the formation of a stable plasma altogether.

If the pressure in the treatment vessel becomes too high, it can be necessary to stop the treatment and manually unblock the filter(s). Consequently, there is a need for methods and apparatus which prevent the vessel filter(s) from becoming blocked over the course of plasma treatment, to allow stable plasma treatment over prolonged periods.

To this end, the treatment vessel of the present invention may have an evacuation port comprising a vessel filter which is protected by a guard element. The guard element blocks particulate material from contacting the vessel filter, whilst still allowing gas to flow to and through the vessel filter.

The glow discharge plasma may be formed in the treatment vessel by supplying a plasma forming feedstock into the treatment vessel, while at the same time removing the waste feedstock through the guard element and then through the vessel filter.

The guard element is not particularly limited and may in principle be any object or barrier which protects the filter.

In one implementation, the guard element is a barrier positioned between the sample and the vessel filter in use, which blocks the movement of sample to the vessel filter. For example, the barrier may be a wall partially or (more preferably) completely surrounding the circumference of the filter. Generally, the treatment vessel is a drum capped by end-plates, with the vessel filter(s) provided on one or both end-plate(s), generally spaced form the edges of the end-plate so as to be placed above the level of the sample in use. The guard element may comprise a wall extending from the end-plate into the interior of the treatment vessel and at least partially surrounding/encircling the filter element. In such instances, the wall serves as a lip which prevents material from lifting up the walls of the treatment vessel into the filter. In such implementations, the guard element may take the form of a tube (having any suitable cross-section, such as cylindrical, or square) extending from the end plate and surrounding (e.g. encircling) the vessel filter. In use, the wall extending from the end-plate does not contact the sample, for example, in embodiments in which the guard element is a tube, the tube does not sweep through the sample. In addition, it is preferred for the wall to extend away from the end-plate for only a relatively short distance, since long walls from the end-plate could interfere with plasma formation. For example, the wall (preferably tube) may extend no more than 30%, no more than 20%, or no more than 10% into the interior of the treatment vessel (as measured relative to the distance between the interior surfaces of the end-plates of the treatment vessel). In this regard, the guard element should be distinguished from the “contact formations” described in WO 2012/076853 which are specifically positioned to contact and agitate the sample in use.

Alternatively, the guard element may extend (at least in part) from the bottom of the treatment vessel. For example, the guard element may be or comprise a wall extending upwards from the drum's surface to hold back sample from contacting the vessel filter. This wall may take the form of an upstanding wall extending across (e.g. parallel to, but spaced from) the end-plate of the drum. In such instances, the wall acts akin to a dam. Note that this wall is different from the lifter paddles or vanes described in WO 2010/142953 which extend along the axis of rotation to help agitate material, since these lifter formations encourage (instead of prevent) contact of particulate material with the vessel filter.

Optionally, the guard element comprises a wall extending from the end-plate and a wall extending from the drum which together define a structure which surrounds (e.g. boxes in) the vessel filter. The wall from the end-plate and wall from the drum may be connected to form said structure, or may simply extend into close proximity.

The guard element must allow a gas flowpath from the interior of the treatment vessel to the vessel filter. Optionally, this gas flowpath is itself covered with a guard filter, to limit the possibility of particulate material contacting the vessel filter. For example, the guard element may define an opening (such as a throughhole, gap or slit) which is covered by a guard filter. The opening may have a maximum dimension of, for example, less than 200 mm, or less than 100 mm. In a preferred implementation, the apparatus includes a guard element taking the form of a tube having a first end extending into the interior of the treatment vessel, and a second end extending to the exterior of the treatment vessel, the apparatus further comprising a guard filter disposed towards the first end of the tube, and a vessel filter disposed towards the second end of the tube. In such implementations, the guard filter preferably caps the first end of the tube, to prevent sample from accumulating in the tube in front of the guard filter. Suitably, the guard element is a tube protruding through a hole in the end-plate of the treatment vessel, with the interior end of the tube capped by the guard filter and the exterior end of the tube capped by the vessel filter. Advantageously, in such implementations the guard element may be removably held in the end-plate (ideally from the exterior of the treatment vessel), to facilitate easy removable, replacement and/or cleaning.

The guard filter may be identical to the vessel filter. Alternatively, the guard filter may be coarser than the vessel filter. The guard filter may be, for example, a HEPA, ceramic, glass or sintered filter.

As noted above, the guard element helps to slow or even prevent blockage of the vessel filter, allowing maintenance of stable pressure within the treatment vessel for extended periods of time, and thereby allowing reliable production of plasma with minimisation of arc formation. The increase in pressure within the treatment vessel may be, for example, less than 5% per hour, less than 10% per hour, less than 15% per hour, or less than 20% per hour, as measured for a set rate of gas delivery to the treatment vessel, at a constant temperature (the latter potentially necessitating temperature control taught below, or necessitating measurement at the point at which the temperature has reached a steady equilibrium value during processing). Within a given treatment step preferably, the pressure variation may be less than ±20% of the mean pressure in millibar, preferably less than ±10%, particularly preferably less than ±5%.

### Apparatus

The apparatus for use in the method of the present invention also constitutes a separate aspect of the invention. Thus, in a second aspect the present invention provides treatment apparatus comprising:
a treatment vessel
an electrode and counter-electrode for generating plasma within the treatment vessel;
a gas supply line fluidly connected to the treatment vessel, for delivering a gaseous plasma forming feedstock to the treatment vessel, the gas supply line connected to a gas flow controller; and
a reagent supply system comprising a reagent dosing controller, for delivery of a liquid or solid reagent to the treatment vessel;
wherein the gas flow controller and reagent dosing controller allow independent control of the rate of delivery of a gaseous plasma forming feedstock and reagent to the treatment vessel.

The treatment apparatus may have any of the optional and preferred features set out above.

### Liquid Reagent

Optionally, the reagent is a liquid.

The liquid reagent may be delivered into the treatment vessel in the form of, for example, a stream, droplets, or a vapour. The droplets may take the form of an aerosol.

The type of liquid reagent used in the methods according to the present invention is not particularly limited and the method according to the present invention may be used with all types of liquid reagent including pure liquid compounds, solutions, emulsions, gels and ionic liquids.

Optionally, the liquid reagent is a non-volatile liquid. As explained above, these types of reagent are not amenable to delivery via the bubbler system taught in WO 2015/145172.

The non-volatile liquid may be defined as a liquid which has a vapour pressure of less than 3 kPa at 25° C. measured at 1 atmosphere, preferably a vapour pressure of less than 2 kPa, more preferably a vapour pressure of less than 1 kPA.

The liquid reagent may be a silane, for example, vinyltrimethoxysilane (VTEO), (3-Aminopropyl)triethoxysilane (APTES), (3-(2,3-Epoxypropoxy)propyl]trimethoxy silane)(GLYMO) or hexamethyldisiloxane (HMDSO)).

The liquid reagent may be a solution, having a compound dispersed in a solvent. The solvent may be, for example, water. The compound may be any suitable molecule for functionalising the sample.

The liquid reagent may be, or comprise, a salt. The salt may be in the form of an ionic liquid or a salt solution, e.g. an aqueous salt solution.

The liquid reagent may be, or comprise, an acid.

In certain embodiments, the liquid reagent may be water, hydrogen peroxide or an alcohol.

As explained above, in instances where the reagent is a liquid reagent, the reagent dosing controller is preferably a pump, such as a positive displacement pump, for example a piston or peristaltic pump. Alternatively, the pump could be any form of dynamic pump or gravity fed pump.

Optionally, the method according to the present invention may involve the step of providing said reservoir of liquid reagent (for example, filling the syringe of a syringe pump) and programming the reagent dosing controller. Optionally, the apparatus may comprise a holding tank for the reagent and a pump for driving the reagent into the treatment vessel. The liquid dosing systems described above may also comprise an additional (second) liquid flow controller subsequent to said reagent dosing controller, to further manipulate/control the rate of flow of liquid into the treatment vessel. This may be useful to limit the opportunity for liquid being unintentionally drawn into the treatment vessel by the low pressure conditions in the treatment vessel.

### Solid Reagent

Optionally, the reagent is a solid.

In order to faciliate efficient addition of the solid reagent into the treatment vessel the solid reagent is preferably a particulate reagent (e.g. powder or pellet). Without wanting to be bound by any theory, it is believed that making use of a particulate solid reagent also facilitates more efficient and controllable reactions than when large pieces of solid reagent are added into the treatment vessel.

The solid reagent may be delivered directly into the treatment vessel. However, more preferably, the solid reagent is entrained by a gas (the gaseous plasma forming feedstock or another carrier gas), to carry the solid reagent into the treatment vessel as an aerosol (a so called solid aerosol volatisation system). Entrainment of the solid in a gas occurs after the reagent dosing controller. Providing the solid as an aerosol means that it can easily reach all areas of the treatment vessel leading to homogeneous functionalisation across the surface of the material.

The solid may be delivered from a storage container (for example, a hopper). In certain embodiments, the storage container is kept under vacuum or kept under the same gas as is used to form the glow discharge plasma, to prevent the introduction of unwanted gases (e.g. atmospheric oxygen or nitrogen) which might disturb plasma formation and cause the formation of electrical arcs.

As mentioned above, the solid may also be delivered as an aerosol, by forming an aerosol with a gas such as nitrogen or argon and then injecting the gas into the treatment vessel. In such cases, the aerosol gas may be the same as the plasma forming feedstock.

Alternatively or additionally, the solid delivery system may function by allowing the relatively low pressure in the treatment vessel to draw the solid into the treatment vessel from a storage container where the solid is stored under a gas at higher pressure.

The type of solid reagent used in the methods according to the present invention is not particularly limited and the method according to the present invention may be used with all types of solid reagent including molecular solids, covalent solids, ionic solids and metals.

The solid reagent may be a metal. For example, the solid reagent may be copper, silver, gold or platinum. In certain embodiments the solid reagent may be a precious metal, such as silver, gold or platinum.

The solid reagent may be activated by the glow discharge plasma. For example, the solid reagent may break down into one or more reactive species upon contact with the glow discharge plasma. Suitable reagents for this purpose include salts, such as metal salts which dissociate in the glow discharge plasma. For example, the salt may be copper formate, which dissociates into copper ions and carbon dioxide in the presence of the glow discharge plasma, with the copper ions being used to decorate the sample and carbon dioxide being exhausted from the system.

### Gaseous Plasma Forming Feedstock

The gaseous plasma-forming feedstock may be, for example, oxygen, nitrogen, argon or any other noble gases. Preferably, the gaseous plasma forming feedstock is argon.

When the plasma-forming feedstock is mixture of gases, the apparatus may also comprise a mass flow controller for mixing gases. This means that two or more gases can be mixed together efficiently. A mixture of gases can then be fed into the treatment vessel in one or more of the treatment steps. Additionally, the apparatus may comprise an automatic safety purge system, this allows the gas lines to be purged of gas prior to the beginning of the treatment step.

### Sample Types

The type of sample which can be subjected to treatment using the methods of the present invention is not restricted. The sample may be an organic material or an inorganic material. Preferably, the sample is a particulate material, in particular a nanomaterial.

The sample may be a carbon material (such as carbon nanotubes, carbon nanorods, or graphitic or graphene platelets, including graphene nanoplatelets), boron nitride, zinc oxide, a nanoclay, a ceramic, a semiconductor material, a polymer or plastics material. Preferably the material is a carbon material or boron nitride. More preferably the material is a carbon material. Most preferably the material is graphite.

The methods set out herein are particularly well-suited to samples made up of a collection/mixture of small discrete parts. For example, the sample may be a particulate (e.g. powdered) material, or even a plurality of products (such as polymer or metal components, e.g. washers, nuts and bolts). Preferably, the sample is a particulate sample. The methods set out above in which the sample is agitated during use are of particular utility to these samples made up of small discrete parts, since the agitation ensures homogeneous treatment of large volumes of material.

Particulate material may be of any size, from pellets and crumb material (generally on the scale of millimetres, to microparticles, having average sizes in the range of 1 to 1000 μm) or nanoparticles (having average sizes in the range of 1 to 1000 nm). Within the meaning of this invention “nanoparticles” are particles having a thickness (i.e. one dimension) of from 1 to 1000 nm, the other dimensions (length and width) may be greater than the thickness e.g. up to 10 times, or up to 100 times or up to 1000 times the thickness.

The present inventors have found the methods set out above to be particularly effective in the treatment of particulate carbon material. These types of material are attractive for use as fillers in polymer composite materials, but generally require modification of their surface chemistry to allow effective dispersal in a matrix material. Thus, it is desirable to tailor the surface chemistry of the materials by adding, altering or removing selected chemical groups to the surface of the materials using the methods of the present invention.

The particulate carbon material being treated may consist of or comprise graphitic carbon, such as mined graphite, which is exfoliated by the treatment. After the treatment the treated material may comprise or consist of discrete graphitic or graphene platelets having a platelet thickness less than 100 nm and a major dimension perpendicular to the thickness which is at least 10 times the thickness. In a preferred embodiment, the particulate carbon material may be GNPs (Graphene nanoplatelets), FLG (few layered graphene) or MWCNTs (Multi walled carbon nanotubes).

The graphene platelets may have a thickness of less than 100 nm and a major dimension (length or width) perpendicular to the thickness. The platelet thickness is preferably less than 70 nm, preferably less than 50 nm, preferably less than 30 nm, preferably less than 20 nm, preferably less than 10 nm, preferably less than 5 nm (this is based on >90% of the particles having these properties, measured using light scattering by a Zetasizer Ultra). The major dimension is preferably at least 10 times, more preferably at least 100 times, more preferably at least 1,000 times, more preferably at least 10,000 times the thickness. The length may be at least 1 times, at least 2 times, at least 3 times, at least 5 times or at least 10 times the width.

### Treatment Types

The treatment applied in the method of the invention may be or include a disaggregating, deagglomerating, exfoliating, cleaning, functionalising, or quenching step, or some combination of these effects.

The treatment may be a multi-step process. In cases, where there is more than one treatment step the effect of the first treatment step may be different to that of subsequent treatment steps. For example, the first treatment step may be a cleaning step, and the second treatment step may be a disaggregating/functionalising step.

Preferably, at least one of the treatment steps is a functionalisation step.

In the functionalisation steps, the treated sample may be chemically functionalised by the liquid or solid reagents which are supplied to the treatment vessel, forming e.g. silane, acid or metal functionalities on their surfaces. These steps may lead to decoration of the surface of the sample.

The term “decoration” is understood to refer broadly to the deposition of one or more materials onto the sample. Decoration may be in the form of a coating of the material. Alternatively, decoration may be in the form of a plurality of discrete deposits of the sample at a number of different sites. In these embodiments, surface modification may be manifest as a plurality of discrete structures or ‘islands’ of material. Particles may be provided which are decorated with a plurality of discrete structures or ‘islands’ of silicon. This gives rise to useful properties, such as an ability for the silicon structures to expand and contract independently of each other. Without wanting to be bound by any theory, it is believed that the plasma activates the reagent as a vapour, for example by ionising the vapour. The vapour which comes into contact with the substrate can then go on to react using the energy from the plasma, which is over the required activation energy.

The method may involve applying a quenching step after the functionalisation step(s). By “quenching” we mean applying a treatment to deactivate certain reactive groups remaining after functionalisation. This may help prevent the groups on the surface of the material from being degraded when exposed to oxygen in the air. For example, the quenching step may involve performing a treatment step using hydrogen gas as the feedstock.

Plasma treatment of the present invention can allow dimensional treatment directed only at exposed surfaces, thus maintaining the structural integrity of the materials being treated.

Cleaning steps may be carried out before all other treatment steps, between other treatment steps and/or after all other treatment steps. For example, the first treatment step may be a cleaning step. Alternatively, the first treatment step may be a disaggregating/functionalising step, and the second treatment step may be a final cleaning step. Cleaning steps can be carried out with an inert gas such as argon.

The treatment steps according to the present invention may comprise: forming a glow discharge plasma in the treatment vessel using a plasma forming feedstock; and subsequently supplying a liquid and/or solid reagent into the treatment vessel whilst maintaining the glow discharge plasma.

Alternatively, the glow discharge plasma may be formed in the treatment vessel at the same time as the liquid or solid reagent is supplied to the treatment vessel.

The method according to the present invention may comprise
a first functionalisation step; and
a second functionalisation step;
   wherein the gaseous plasma forming feedstock and/or reagent supplied in the first functionalisation step is different to that supplied during the second functionalisation step.

This may involve a first functionalisation step in which the sample is surface-functionalised by the gaseous glow discharge plasma forming feedstock and a subsequent step in which a liquid or solid reagent is supplied into the treatment vessel whilst maintaining a glow discharge plasma in order to functionalise the material with a liquid or solid reagent. Optionally, the first functionalisation step introduces a functional group which is subsequently modified by the second functionalisation step—for example, through addition to or cleavage of the initial functional group.

For example, the first functionalisation step may involve using oxygen gas as the gaseous plasma forming feedstock to form a sample which is surface functionalised with oxygen functionalities. The second functionalisation step may then involve using argon gas as the gaseous plasma forming feedstock whilst concomitantly supplying a liquid or solid reagent into the treatment vessel which provides the second functional group to functionalise the sample, such as a silane group.

The treatment step may also comprise the use of a sacrificial electrode for sputtering treatment of the sample. For example, metal decoration may be performed by producing a plasma using electrodes formed from or coated with a decorant metal. The use of a sacrificial electrode is in addition to the delivery of a reagent into the treatment vessel under the control of a reagent dosing controller.

### PREFERRED EMBODIMENTS

Particularly preferred embodiments include:

A method for treating a sample using glow discharge plasma in an apparatus comprising a treatment vessel, an electrode and a counter electrode wherein the electrode is connected to a power supply, the method comprising:
delivering a gaseous plasma forming feedstock into the treatment vessel through a gas supply line under the control of a gas flow controller, and causing formation of a glow discharge plasma in the treatment vessel from the gaseous plasma forming feedstock; and simultaneously
delivering a liquid reagent into the treatment vessel under the control of a reagent dosing controller, and
contacting the sample with the glow discharge plasma and the reagent; wherein the gas flow controller and the reagent dosing controller allow independent control of the rate of delivery of the gaseous plasma forming feedstock and the liquid reagent
wherein the method involves applying a voltage between the electrode and the counter electrode to cause the formation of the glow discharge plasma within the treatment vessel, and wherein the reagent dosing controller is a pump.

Preferably, the reagent dosing controller is a syringe pump, or peristaltic pump but can be any form of positive displacement pump.

Preferably, the liquid is a silane such as vinyltrimethoxysilane (VTEO), (3-Aminopropyl)triethoxysilane (APTES), (3-(2,3-Epoxypropoxy)propyl]trimethoxy silane)(GLYMO) or hexamethyldisiloxane (HMDSO)).

Preferably, the treatment vessel is agitated, preferably rocked back and forth about an axis to cause agitation of the sample,

Preferably, the treatment vessel is a temperature-controlled treatment vessel, with the temperature is held at a constant temperature of from about −20° C. to 120° C. during the method.

In a further particularly preferred embodiment, the present invention relates to a method for treating a sample using glow discharge plasma in an apparatus comprising a treatment vessel, an electrode and a counter electrode wherein the electrode is connected to a power supply, the method comprising:
delivering a gaseous plasma forming feedstock into the treatment vessel through a gas supply line under the control of a gas flow controller, and causing formation of a glow discharge plasma in the treatment vessel from the gaseous plasma forming feedstock; and simultaneously
delivering a solid reagent into the treatment vessel under the control of a reagent dosing controller, and
contacting the sample with the glow discharge plasma and the reagent; wherein the gas flow controller and the reagent dosing controller allow independent control of the rate of delivery of the gaseous plasma forming feedstock and the solid reagent
   wherein the method involves applying a voltage between the electrode and the counter electrode to cause the formation of the glow discharge plasma within the treatment vessel.

Preferably, the reagent dosing controller is a conveyor system.

Preferably, the solid reagent is combined with a gas before delivery into the treatment vessel and is delivered as an aerosol into the treatment vessel.

Preferably, the solid reagent is delivered from a storage container kept under vacuum.

Preferably, the solid reagent is a precious metal.

In these preferred embodiments, the treatment vessel is preferably rocked back and forth about an axis to cause agitation of the sample, with the solid reagent being delivered to the treatment vessel through a reagent port provided along the said axis. Preferably, the electrode is positioned along the axis and the reagent port is provided on the electrode.

In a further particularly preferred embodiment, the present invention relates to an apparatus suitable for treating a sample in a method according to the present invention, the apparatus comprising
a treatment vessel,
a gas supply line fluidly connected to the treatment vessel for delivering a gaseous plasma forming feedstock to the treatment vessel,
a gas flow controller connected to the gas supply line and
a reagent supply system comprising a reagent dosing controller, for delivery of a liquid or solid reagent to the treatment vessel
wherein, the gas flow controller and the reagent dosing controller allow independent control of the rate of delivery of a gaseous plasma forming feedstock and reagent to the treatment vessel,
wherein the apparatus further comprises an electrode and counter electrode for generating plasma within the treatment vessel and
preferably wherein the treatment vessel is provided with a temperature control system for controlling the temperature of the treatment vessel during the treatment method.

Preferably, the treatment vessel is a treatment drum which is rotatable about a stationary axle.

Preferably, the axle comprises or serves as the electrode.

Preferably, the apparatus further comprises a vacuum system incorporating a vacuum pump and a vacuum pump valve configured to control the level of vacuum applied by the vacuum pump to the treatment vessel.

### Other Aspects

In an alternative aspect of the invention, the present invention provides plasma apparatus comprising a treatment vessel and a mechanical or motorised injection system for delivering liquid into the treatment vessel during operation. The mechanical or motorised injection system may be suitable for directly injecting liquid into the treatment vessel. Optionally, the apparatus is configured to allow concomitant supply of a plasma-forming gas to the treatment vessel with the liquid. The invention also provides a method of plasma treating a sample held within a treatment vessel, comprising forming a plasma within the treatment vessel and delivering liquid using a mechanical or motorised injection system.

### BRIEF DESCRIPTION OF THE FIGURES

The present proposals are now explained further with reference to the accompanying figures in which:

FIG. 1 is a diagram showing a plasma treatment apparatus according to the present invention;

FIG. 2 is a diagram of the injector system;

FIG. 3 is a diagram of the fluid delivery system for the plasma treatment apparatus;

FIG. 4 shows the mechanism of attachments of APTES to an oxygenated graphene;

FIG. 5 is an XPS scan of untreated graphene materials;

FIG. 6 is an XPS scan of silanated graphitic materials using the process according to the present invention;

FIG. 7 is an XPS scan of raw boron nitride;

FIG. 8 is an XPS scan of silanated boron nitride using the process according to the present invention with HMDSO as the reagent;

FIG. 9 is an XPS scan of silanated boron nitride using the process according to the present invention with GLYMO as the reagent.

### DETAILED DESCRIPTION

Unless defined otherwise, all technical and scientific terms used herein have the same meaning as commonly understood by one of ordinary skill in the art to which the invention pertains. Although, any methods and materials similar or equivalent to those described herein can be used in practice for testing of the present invention, the preferred materials and methods are described herein. In describing and claiming the present invention, the following terminology will be used in accordance with the definitions set out below. Unless clearly indicated otherwise, use of the terms “a,” “an,” and the like refers to one or more.

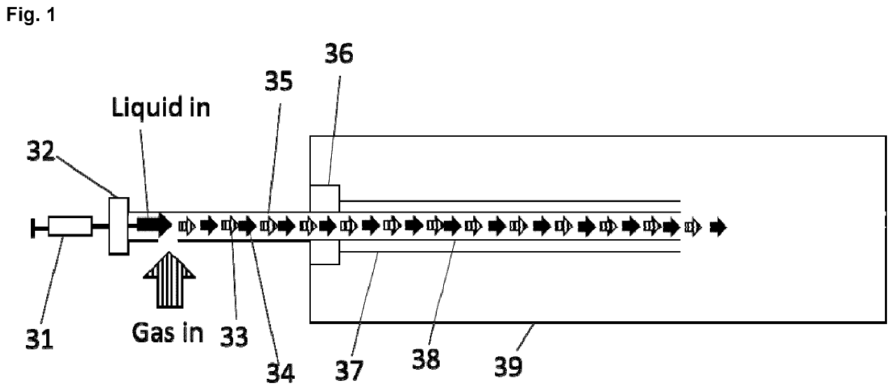

FIG. 1 is diagram of a plasma treatment apparatus according to the present invention, for delivering a liquid reagent. The apparatus consists of a treatment vessel 39 mounted on a electrode 37 via mounting plate 36, with electrode 37 and mounting plate 36 serving as an axle around which the treatment vessel rotates during operation. The treatment vessel 39 serves as a counter-electrode, such that a glow discharge plasma can be created within the treatment vessel through applying a voltage between electrode 37 and treatment vessel 39.

Electrode 37 includes a hollow channel 38 for the delivery of plasma-forming feedstock into the treatment vessel. Channel 38 is integrally formed with a feed channel 35, onto which the plasma-forming feedstock supplies are attached. Two different supply routes are provided. Firstly, a liquid-filled syringe 31 is secured to channel 35 by a grommet 32. Secondly, channel includes an inlet for a gaseous feedstock 33, close to the exit of the liquid-filled syringe, such that liquid delivered from the syringe is entrained by the gaseous feedstock 33 during operation. Delivery of the gaseous feedstock 33 is controlled by a mass flow controller (not shown).

To use the equipment, a sample is loaded into the treatment vessel 39, via a removable lid. The pressure in the treatment vessel is reduced by applying a vacuum to an evacuation port on the vessel housing. Next a gaseous feedstock is supplied to the treatment vessel interior with a liquid reagent entrained in the gas via the channel 38 in the electrode, and a voltage applied between electrode 37 and treatment vessel 39 to cause formation of a glow discharge plasma. During processing, the treatment vessel 39 is rotated relative to the housing, such that the sample held in the treatment vessel is tumbled through the plasma. The sample may be rotated by continuously rotating the treatment vessel or alternatively the treatment vessel may be rocked back and forth.

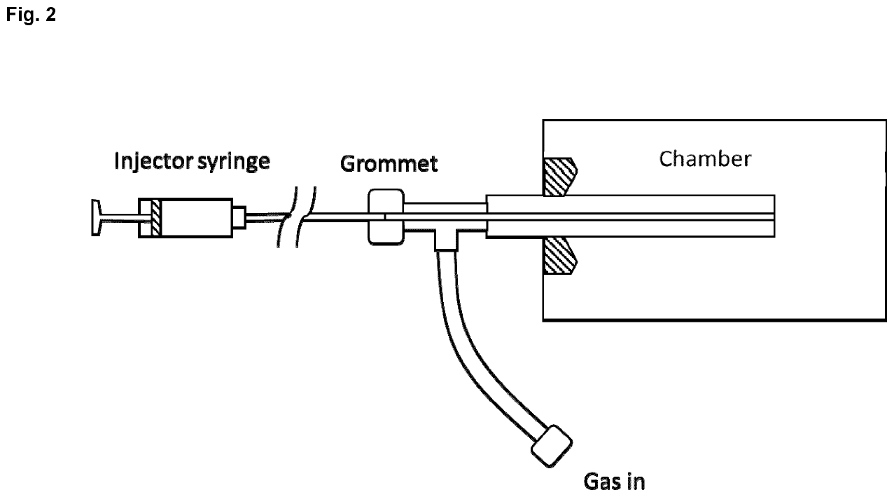

FIG. 2 is a diagram of an injection unit for delivering liquids into the treatment vessel. The injection unit comprises an injector syringe, a channel leading into the treatment chamber, a grommet through which the needle of the syringe can be pushed in order to carry out the injection step and a gas inlet to the channel into the treatment vessel.

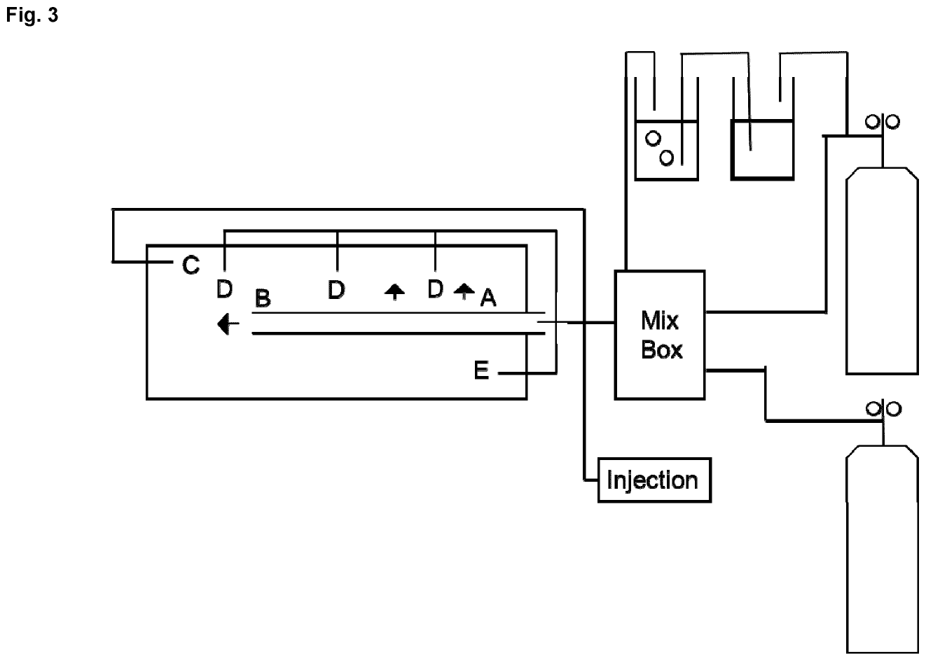

FIG. 3 is a diagram of the how gas, liquids or vapours may be delivered to a treatment vessel. Gases, liquids or vapours may be delivered through vents along the length of a central electrode A, through a vent at the end of a central electrode B, through vents in the front wall of the treatment vessel C, through vents in the side walls of the treatment vessel D or through vents in the rear wall of the treatment vessel. An injection unit allows liquid or vapour to be delivered into the treatment vessel. A mix box comprising a mass flow controller allows two or more different gases to be fed into the treatment vessel. The gas lines may also contain bubblers allowing volatile liquids to be delivered into the treatment vessel as vapours. The gas lines may also comprise trace heaters, which allow the gas lines to be held at a particular temperature.

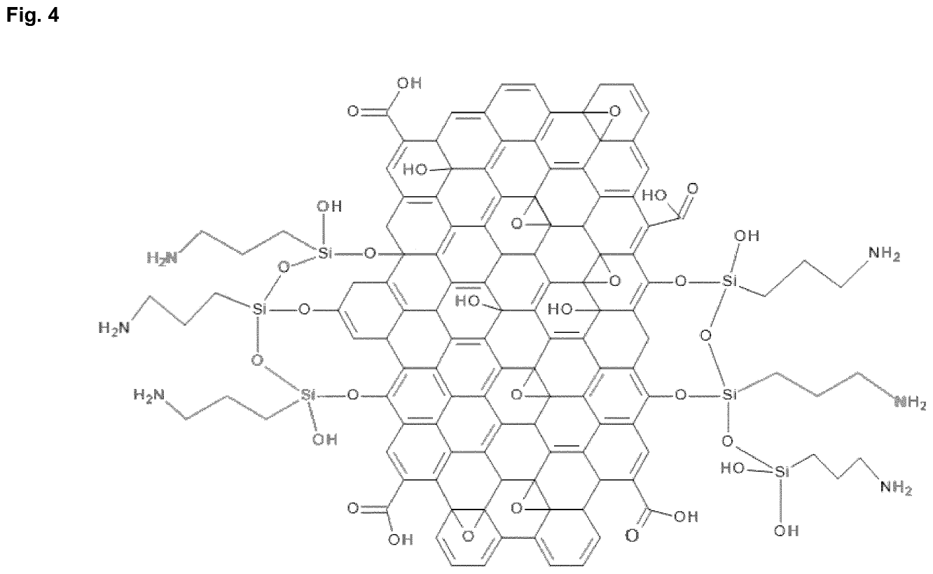

FIG. 4 is a diagram showing the mechanism of attachment of APTES to oxygenated graphene. The APTES reacts with (condenses with) functional groups containing oxygen on the surface of the graphene. This condensation reaction results in the cross-linking of the oxygen containing functional groups on the surface of the graphene.

### EXAMPLES

### Example 1

The plasma treatment apparatus incorporating a system for delivering a liquid into the treatment vessel according to FIG. 1 was used to demonstrate that the plasma treatment apparatus could be used for silane functionalisation.

Tests were conducted with graphitic materials. A sample of graphitic material was loaded into the treatment vessel and subjected to treatment with plasma, formed using argon gas at 0.7 mbar with 50 W of power supplied via a 1.5 kV transformer for 60 minutes. GLYMO liquid was delivered using the injector system at a rate of 10 mL/hour. The weight percentage of carbon, oxygen, nitrogen, silicon and sulfur was determined using X-Ray Photoelectron Spectroscopy (XPS).

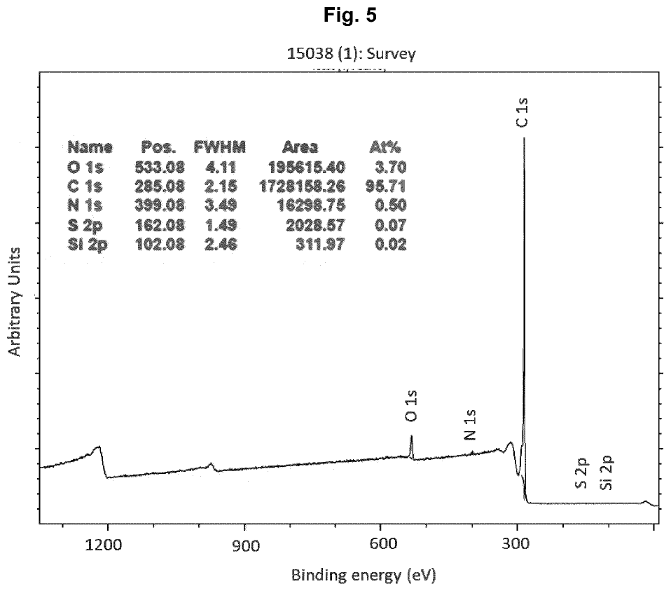

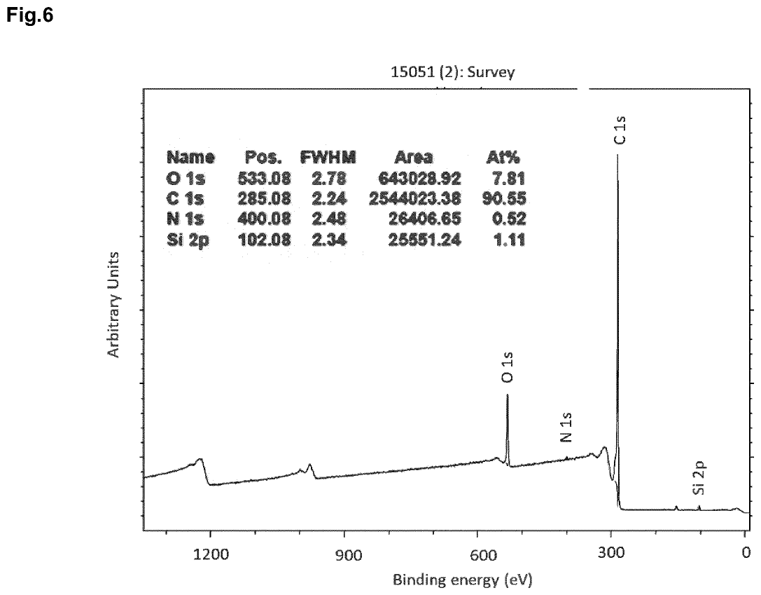

The spectrum for before the treatment is shown in FIG. 5, the spectrum for after the treatment are shown in FIG. 6.

### Example 2

The plasma treatment apparatus incorporating a system for delivering a liquid into the treatment vessel according to FIG. 1 was used to demonstrate that the plasma treatment apparatus could be used for silane functionalisation.

Tests were conducted with boron nitride.

### Example 2a

A sample of boron nitride was loaded into the treatment vessel and subjected to treatment with plasma, formed using oxygen gas at 0.7 mbar with 50 W of power supplied via a 1.5 kV transformer for 60 minutes. HDMSO liquid was delivered using the injection system at a rate of 10 mL/hour. The weight percentage of carbon, oxygen, nitrogen, silicon, boron and sulfur was determined using X-Ray Photoelectron Spectroscopy (XPS).

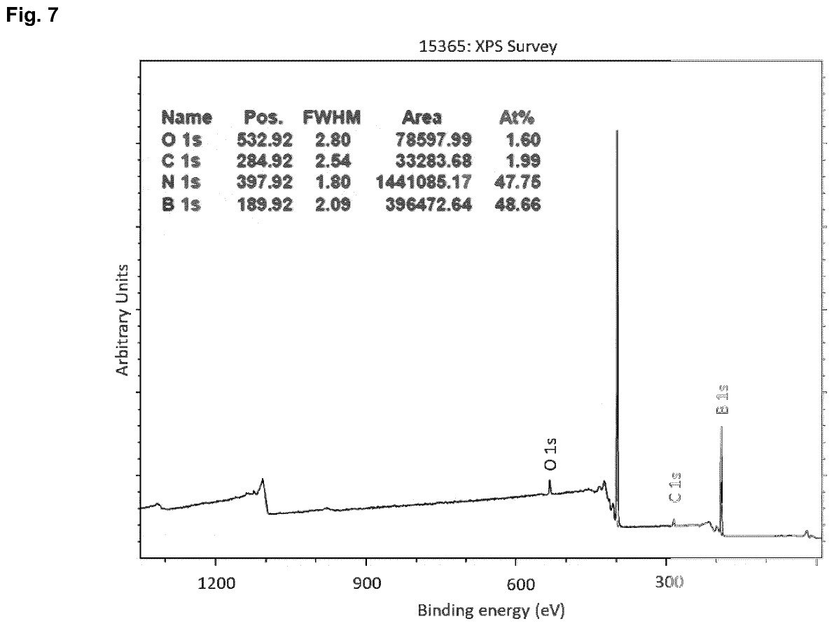

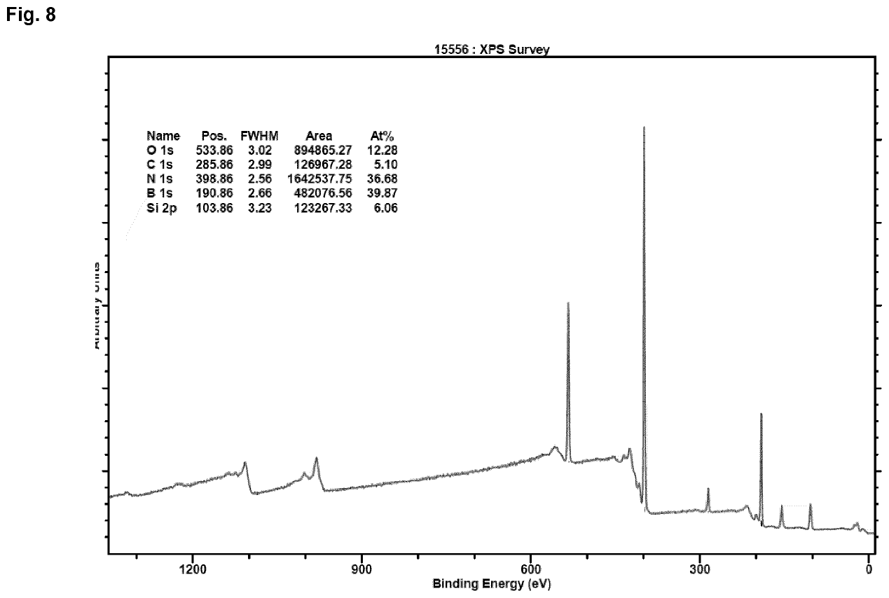

The spectrum for before the treatment is shown in FIG. 7, the spectrum for after the treatment is shown in FIG. 8.

### Example 2b

A sample of boron nitride was loaded into the treatment vessel and subjected to treatment with plasma, formed using argon gas at 0.7 mbar with 50 W of power supplied via a 1.5 kV transformer for 60 minutes. GLYMO liquid was delivered using the injection system at a rate of 10 mL/hour. The weight percentage of carbon, oxygen, nitrogen, silicon, boron and sulfur was determined using X-Ray Photoelectron Spectroscopy (XPS).

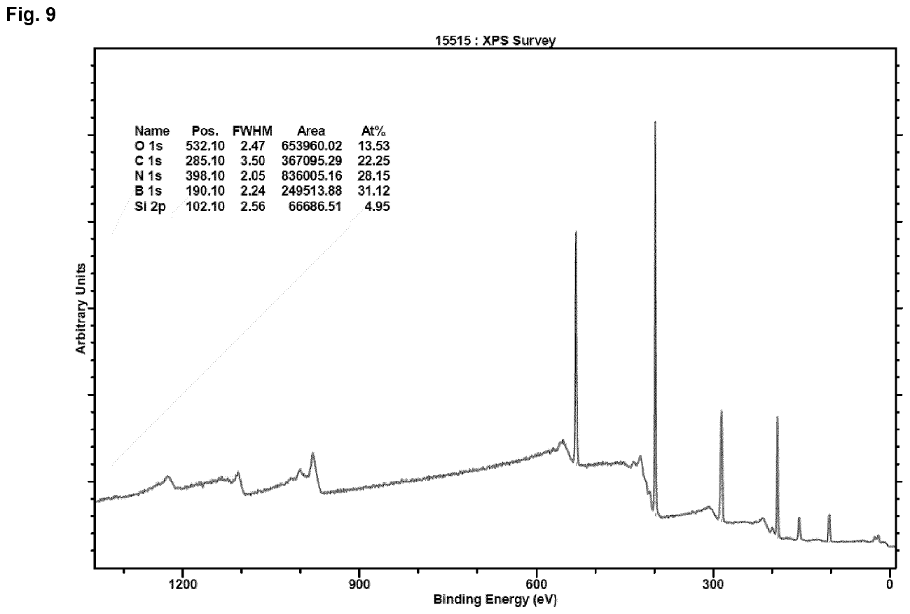

The spectrum for before the treatment is shown in FIG. 7, the spectrum for after the treatment is shown in FIG. 9.

The results of these experiments (examples 2a and 2b) show that both carbon and boron nitride show a marked increase in silicon from the XPS scans. The high vacuum used in XPS is known to remove volatiles, so it can be concluded that the silanes are chemically bonded to the respective substrates. These examples also demonstrate silane treatment with a number of different reagents.

### Example 3

The plasma treatment apparatus according to FIG. 1 was used to demonstrate that the plasma treatment apparatus could be used for silane functionalisation.

Two different graphitic materials were treated under similar conditions to those used in example 2. The results of these tests are given in table 1 below.

TABLE 1

| | | | | |
|---|---|---|---|---|
| O1s | C1s | N1s | F1s | Si2p |

Material: Edge Oxidised Graphene Oxide¹

| | | | | | |
|---|---|---|---|---|---|
| Raw (Ave) | 4.86 | 94.53 | 0.61 | 0 | 0 |
| Treated | 8.87 | 90.24 | 0.59 | 0 | 0.29 |

Material: Graphene Nanoplatelets²

| | | | | | |
|---|---|---|---|---|---|
| Raw (Ave) | 4.28 | 95.35 | 0 | 0 | 0.3 |
| Treated | 6.95 | 90.29 | 0.96 | 0.05 | 1.75 |

¹The power was modulated during the treatment of the edge oxidised graphene oxide;
²The power was held at a constant level during the treatment of the graphene nanoplatelets.

Experiments demonstrated that silicon can be incorporated onto the surface of the carbon materials after treatment.

The above experiments demonstrate that the liquid injection system can be used to provide plasma feedstocks to effectively functionalise the carbon and boron nitride materials.

1. A method for treating a sample using glow discharge plasma in an apparatus comprising a treatment vessel, the method comprising:
delivering a gaseous plasma forming feedstock into the treatment vessel through a gas supply line under the control of a gas flow controller, and causing formation of a glow discharge plasma in the treatment vessel from the gaseous plasma forming feedstock; and simultaneously
delivering a reagent into the treatment vessel under the control of a reagent dosing controller, wherein the reagent is a liquid or a solid; and
contacting the sample with the glow discharge plasma and the reagent; wherein the gas flow controller and the reagent dosing controller allow independent control of the rate of delivery of the gaseous plasma forming feedstock and the reagent.

2. A method according to claim 1, wherein the reagent is a liquid.

3. A method according to claim 2, wherein the reagent dosing controller is a pump.

4. A method according to claim 3, wherein the pump is a positive displacement pump.

5. A method according to claim 4, wherein the pump is a piston pump or a plunger pump.

6. A method according to claim 5, wherein the pump is a syringe pump.

7. A method according to claim 2, wherein the liquid is a non-volatile liquid.

8. A method according to claim 2, wherein the liquid is a silane.

9. A method according to claim 1, wherein the reagent is a solid.

10. A method according to claim 9, wherein the reagent dosing controller is a conveyor system or a pellet gate system.

11. A method according to claim 10, wherein the reagent dosing controller is a conveyor system.

12. A method according to claim 9, wherein the solid is a metal.

13. A method according to claim 12, wherein the metal is a precious metal.

14. A method according to claim 1, wherein the reagent dosing controller is adjustable to allow the rate of delivery of the reagent to be varied during the method for treating the sample.

15. A method according to claim 1, wherein the reagent dosing controller is continuously adjustable.

16. A method according to claim 1, wherein the reagent is combined with a gas before delivery into the treatment vessel, preferably wherein the reagent is delivered into the treatment vessel as an aerosol.

17. A method according to claim 1, wherein the gas flow controller is a gas regulator, a mass stream controller or a mass flow controller.

18. A method according to claim 1, wherein the apparatus comprises a vacuum pump in fluid communication with the treatment vessel and a vacuum pump valve configured to control the level of vacuum applied by the vacuum pump to the treatment vessel.

19. A method according to claim 18, wherein the apparatus further comprises a pressure feedback system which obtains pressure data from the treatment vessel and actuates the vacuum pump valve based on the pressure data.

20. A method according to claim 1, wherein the sample is a particulate sample.

21. A method according to claim 1, wherein the sample is agitated by rotating the treatment vessel about an axis during treatment.

22. Apparatus suitable for treating a sample in a method as defined in claim 1, the apparatus comprising:
a treatment vessel,
a gas supply line fluidly connected to the treatment vessel for delivering a gaseous plasma forming feedstock to the treatment vessel,
a gas flow controller connected to the gas supply line and
a reagent supply system comprising a reagent dosing controller, for delivery of a liquid or solid reagent to the treatment vessel
wherein, the gas flow controller and the reagent dosing controller allow independent control of the rate of delivery of a gaseous plasma forming feedstock and reagent to the treatment vessel.

23. Apparatus according to claim 22, wherein the reagent dosing controller is a pump.

24. Apparatus according to claim 23, wherein the pump is a syringe pump or a peristaltic pump.

25. Apparatus according to claim 22, wherein the reagent dosing controller is a conveyor system.
